(19) United States
(12) Patent Application Publication
(10) Pub. No.: US 2015/0243825 A1
(43) Pub. Date: Aug. 27, 2015

(54) SIMULTANEOUS DUAL-BAND DETECTOR

(71) Applicant: Raytheon Company, Waltham, MA (US)

(72) Inventors: Craig Keasler, Santa Barbara, CA (US); Justin Gordon Adams Wehner, Goleta, CA (US); Richard H. Wyles, Santa Barbara, CA (US); Donald F. King, Ventura, CA (US); Peter C. Roberts, Newbury Park, CA (US); Christopher L. Mears, Boulder, CO (US)

(73) Assignee: Raytheon Company, Waltham, MA (US)

(21) Appl. No.: 14/191,933

(22) Filed: Feb. 27, 2014

(51) Int. Cl. H01L 31/101; H01L 31/0352

(52) U.S. Cl. CPC H01L 31/1013; H01L 31/035281; G01J 2005/202

(57) ABSTRACT

A radiation detector having a pair of adjacent mesas disposed on a common layer. The common layer comprises a first semiconductor layer having a first conductivity type and an energy bandgap responsive to radiation in a first spectral region. Each of the mesas comprises: a second semiconductor; and a third semiconductor layer disposed on the second semiconductor layer having the first conductivity type and an energy bandgap responsive to radiation in a second spectral region. The second semiconductor layer may have a conductivity type opposite the first conductivity type or the three layers may provide an nBn or pBp structure. The third semiconductor layer of the second mesa produces minority carriers, in response to the radiation in the second spectral region, flowing as unwanted carriers into the common layer towards the first mesa. A barrier region is disposed in the common layer to prevent the unwanted carriers from passing from the second mesa to the first mesa.

### TECHNICAL FIELD

This disclosure relates generally to focal plane arrays, and relates specifically to staring focal plane arrays that employ integrated photovoltaic detectors for simultaneously detecting infrared (IR) radiation within a plurality of different spectral bands (e.g., “two-color detectors”).

### BACKGROUND

As is known in the art, imaging systems typically use an array of detectors to generate an image of a target. Each individual detector measures the intensity of electromagnetic wave energy or radiation (such as infrared (IR) radiation or visible light radiation) incident upon the detector element, and forms one pixel of the output image. In some applications it is desirable to detect energy in two different colors or wavelengths; that is each pixel has sensitivity in two different spectral bands. The spectral bands may include short wavelength IR (SWIR), medium wavelength IR (MWIR), long wavelength IR (LWIR), and very long wavelength IR (VLWIR. An array of two-color IR detectors may be employed in a number of imaging applications wherein it is required to simultaneously detect radiation within two spectral bands from a scene within a field of view of the array. By example, the array may detect LWIR and MWIR, or LWIR and SWIR. Reference in this regard is made to U.S. Pat. No. 5,113,076, issued May 12, 1992, entitled “Two Terminal Multi-band Infrared Radiation Detector” to E. F. Schulte. In this type of device the detection of a particular wavelength band is achieved by switching a bias supply. For example referring to FIG. 1, a back-side illuminated semiconductor radiation detector comprised of Group II-V material, e.g., Hg_{(1.0-x)}CdₓTe, is shown. The detector here is a two-terminal triple layer heterojunction (TLHJ) semiconductor radiation detector including an n-type base layer having an energy bandgap responsive to mid-wavelength IR (MWIR) radiation. A SWIR layer above the base layer a heavily doped p-type short-wave IR (SWIR) responsive layer that forms a heterojunction with the base layer, but does not contribute significant numbers of SWIR photon-generated carriers since most SWIR radiation (e.g., 1000 nm to approximately 4000 nm) does not penetrate through the base layer. Thus, the junction is a short wavelength junction responsive to substantially only MWIR radiation (e.g., 3000 nm to approximately 8000 nm). Above the SWIR layer is provided an n-type long-wave IR (LWIR) responsive layer. The LWIR layer is provided with a thickness great enough to absorb the LWIR radiation (e.g., 7000 nm to approximately 14000 nm) that has penetrated the two underlying layers. A heterojunction is formed between the SWIR and LWIR layers, the heterojunction is a long wavelength junction responding substantially only to LWIR radiation.

The bandgap of the LWIR layer is less than the bandgap of the MWIR layer. The bandgap of the LWIR layer would absorb the electromagnetic wave energy intended for the MWIR layer so the structure is illuminated from the back side, as illustrated. When light is absorbed it generates an electron-hole pair. Electromagnetic wave energy is not absorbed in the SWIR layer because SWIR energy is absorbed in the base layer before it can reach the SWIR layer.

More particularly, in the three layer detector structure of FIG. 1, the two heterojunctions are coupled in series and function electrically as two back-to-back diodes. During use the detector electrode is coupled to a switchable bias source and the polarity of the bias is switched. With the positive bias applied to the MWIR layer the n-p junction between layers LWIR and SWIR is in far forward bias and functions as a low resistance conductor, thereby contributing no significant amount of photocurrent to the circuit while the junction between layers SWIR and MWIR, however, is in a reverse bias condition and modulates the circuit current in proportion to the MWIR photon flux. Conversely, with the negative bias applied to the MWIR layer the junction between layers MWIR and SWIR is in forward bias and contributes no significant photocurrent to the circuit. The junction between layers SWIR and LWIR is reversed biased and produces a current modulation proportional to the LWIR flux incident on the detector. The modulated current is read out in a conventional manner via the readout circuit (not shown).

Referring now to FIG. 2, a different dual color detector is shown. Here, the detector includes a pair of mesa structures in a side by side relationship. The two side by side mesa structures are formed by etching through the layers to form a pair of pixel regions, REGION 1 and REGION 2. The bandgap of the lower n-type layer is greater than the bandgap of the upper n-type doped layer and the bandgap of the p-type layer is greater than both the bandgap of the upper and lower n-type doped layers.

As is known in the art, there are two recognized types of charge carriers in semiconductors. One is electrons, which carry a negative electric charge. In addition, it is convenient to treat the traveling vacancies in the valence band electron population (holes) as the second type of charge carrier, which carry a positive charge equal in magnitude to that of an electron. The more abundant charge carriers are called majority carriers, which are primarily responsible for current transport in a piece of semiconductor. In n-type semiconductors they are electrons, while in p-type semiconductors they are holes. The less abundant charge carriers are called minority carriers; in n-type semiconductors they are holes, while in p-type semiconductors they are electrons. As is also known, when an electron meets with a hole, they recombine and these free carriers effectively vanish. The recombination means an electron which has been excited from the valence band to the conduction band falls back to the empty state in the valence band, known as the hole. The holes are the empty state created in the valence band when an electron gets excited after getting some energy to overpass the energy gap.

Referring again to FIG. 2, ohmic contacts are formed for the two regions, as indicated; the contact for pixel REGION 1 being biased with a negative voltage (forward biasing the junction between the upper n-type layer and the p-type layer (diode 2) while reverse biasing the junction between the p-type layer and the lower n-type layer) to detect carriers, here majority or electron, generated in the lower n-type layer in response to electromagnetic wave energy received having a shorter wavelength λ₁, while the contact in pixel REGION 2 is biased with a positive voltage (reverse biasing the junction between the upper n-type layer and the p-type layer (diode 2) while forward biasing the junction between the p-type layer and the lower n-type layer) to detect minority carriers, here holes, in the upper n-type layer generated in response to electromagnetic wave energy received having a longer wavelength, λ₂.

Considering pixel REGION 2, electromagnetic wave energy received having the longer wavelength, λ₂ generates electron and hole carriers in the upper n-type doped layer and these carriers are separated, as indicated, into holes (h⁺) and electrons (e⁻) by the negative, i.e., reverse, bias across the long wavelength junction (i.e., the junction, or diode 2, formed between the upper n-type layer and the p-type layer) with the electrons e⁻ generating a majority carrier signal through the contact to pixel REGION 2. It is noted that the short wavelength junction (i.e., the junction, or diode 1, formed between the lower n-type layer and the p-type layer) is forward biased and therefore does not separate carriers generated in response to any received short wavelength, λ₁ electromagnetic wave energy.

Considering pixel REGION 1, electromagnetic wave energy received having the shorter wavelength, λ₁ generates electron and hole carriers in the lower n-type doped layer and these carriers are separated, as indicated, into holes (h⁺) and electrons (e⁻) by the negative, i.e., reverse, bias across the short wavelength junction (i.e., the junction, or diode 1, formed between the lower n-type layer and the p-type layer) with the holes h⁺ (minority carriers) in the upper n-type layer thereby generating a minority carrier signal through the contact to pixel REGION 1. It is noted that the long wavelength junction (i.e., the junction, or diode 2, formed between the upper n-type layer and the p-type layer) is forward biased and therefore does not separate carriers generated in response to any received long wavelength, λ₂ electromagnetic wave energy.

Thus, it is noted that: each one of the mesas has a layer doped with the same type dopant, here the upper n-type layer, the contact of each one of the mesas is in ohmic contact with the corresponding doped layer, one of the doped layers produces majority carriers in response to electromagnetic wave energy having the long wavelength and wherein the other one of the doped layers produces minority carriers in response to electromagnetic wave energy of the short wavelength.

It is noted that the holes h⁺ (minority carriers) generated by long wavelength electromagnetic wave energy in pixel REGION 2 are unwantedly injected to REGION 1 by diffusing under the region separating the two mesa structures. These holes h⁺ (minority carriers) from REGION 2 that diffuse into pixel REGION 1 are indistinguishable from the holes h⁺ (minority carriers) that are generated in response to the short wavelength electromagnetic wave energy being detected by minority carrier flow through the contact to the upper n-type layer in pixel REGION 1. Thus, the contact to the upper n-type layer in pixel REGION 1 not only detects the holes h⁺ (minority carriers) flow from short wavelength electromagnetic wave energy but detects long wavelength electromagnetic wave energy as a result of the unwanted injected holes h⁺ (minority carriers) from pixel REGION 2 thereby creating cross talk which corrupts the signal produced by the contact to the upper n-type layer in pixel REGION 1 in response to received short wavelength electromagnetic wave energy.

### SUMMARY

In accordance with the present disclosure, a detector is provided having a pair of adjacent mesas disposed on a common layer. The common layer comprises: a first semiconductor layer having a first conductivity type and an energy bandgap responsive to radiation in a first spectral region. Each of the mesas comprises: a second semiconductor layer disposed on the common layer, and a third semiconductor layer disposed on the second semiconductor layer having the first conductivity type and an energy bandgap responsive to radiation in a second spectral region.

In one embodiment the second layer has a conductivity type opposite the conductivity type of the first layer.

In one embodiment, the second layer is a barrier layer.

In one embodiment, the first, second and third layers provide a nBn or pBp structure.

The third semiconductor layer of the second mesa produces minority carriers, in response to the radiation in the second spectral region, flowing as unwanted carriers into the common layer towards the first mesa. A barrier region is disposed in the common layer to prevent the unwanted carriers from passing from the second mesa to the first mesa.

In one embodiment, a radiation detector is provided having a pair of adjacent mesas disposed on a common layer. The common layer comprises a first semiconductor layer having a first conductivity type and an energy bandgap responsive to radiation in a first spectral region. Each of the mesas comprises: a second semiconductor layer disposed on the common layer having a conductivity type opposite the first conductivity type; and a third semiconductor layer disposed on the second semiconductor layer having the first conductivity type and an energy bandgap responsive to radiation in a second spectral region. The third semiconductor layer of the second mesa produces minority carriers, in response to the radiation in the second spectral region, flowing as unwanted carriers into the common layer towards the first mesa. A barrier region is disposed in the common layer to prevent the unwanted carriers from passing from the second mesa to the first mesa.

In one embodiment, the third semiconductor material has a predetermined doping concentration, and wherein the barrier region is a semiconductor region having the first electrical conductivity type and having as doping concentration greater than the predetermined doping concentration.

In one embodiment, the barrier region comprises a fourth semiconductor layer disposed on the first semiconductor layer, wherein the third semiconductor material has a predetermined doping concentration and wherein the fourth semiconductor layer has first electrical conductivity type and has as doping concentration greater than the predetermined doping concentration.

In one embodiment, the barrier region provides recombination to minority carriers passing through the barrier region between the mesas.

In one embodiment, the recombination region reduces the unwanted carrier passing between the mesas by recombining the unwanted minority carriers with majority carriers in the barrier region.

In one embodiment, the pair of mesas are single crystalline and wherein the barrier region is polycrystalline.

In one embodiment, the barrier region is an implanted region.

In one embodiment, a radiation detector is provided having: a pair of adjacent mesa structures disposed on a common layer, the common layer comprising: a first semiconductor layer having a first type of electrical conductivity and an energy bandgap responsive to radiation in a first spectral region. Each one of the mesa structures, comprises: a second semiconductor layer disposed on with the common layer, the second semiconductor layer having a second type of electrical conductivity opposite the first type of electrical conductivity; a third semiconductor layer disposed on and in contact with the second semiconductor layer, the third semiconductor layer having the first type of electrical conductivity and an energy bandgap responsive to radiation in a second spectral region spectral region. A first one of the mesa structures is coupled to a voltage to reverse bias a junction between the first semiconductor layer and the second semiconductor layer. A second one of the mesa structures is coupled to a voltage to reverse bias a junction between the second layer and the third second semiconductor layer. The third semiconductor layer of the second one of the mesa structures produces minority carriers in response to the radiation in the second spectral region, a portion of such generate minority carriers flowing as unwanted carriers into the common layer towards the first one of the mesa structures. A barrier region is disposed in the common layer between the pair of mesa structures to prevent the unwanted carriers from passing through the barrier region from the second one of the pair of mesa structures to the first one of the pair of mesa structures.

In one embodiment, the third semiconductor material has a predetermined doping concentration, and wherein the barrier region is a semiconductor region having the first electrical conductivity type and having as doping concentration greater than the predetermined doping concentration.

In one embodiment, the barrier region comprises a fourth semiconductor layer disposed on the first semiconductor layer, wherein the third semiconductor material has a predetermined doping concentration and wherein the fourth semiconductor layer has first electrical conductivity type and has a doping concentration greater than the predetermined doping concentration.

With such an arrangement, a simultaneous dual-band detector structure that reduces the flow of carriers between adjacent, side by side, mesa structures each mesa providing a pixel region for the dual band detector, each region being biased for each of the one of the dual bands. A low carrier lifetime layer is placed at the backside of the detector either through growth or implantation to reduce the number of minority carriers that diffuse between the adjacent pixels regions by, for example, increasing recombination of minority carriers and majority carriers. The recombination can be produced by, for example, increasing the doping in a region between the two pixel regions or introducing lattice damage in such region. This layer is sufficiently thick such that all carriers that move from pixel region to a neighboring pixel region must pass through this low carrier lifetime layer. Due to the low lifetime, carriers that would contribute to this crosstalk are instead recombined in the low carrier lifetime layer before reaching the neighboring pixel region. Alternatively, instead of a low lifetime layer, a low lifetime region may be formed between adjacent pixel regions. This low lifetime region may be formed through a patterned ion implantation. Usually low lifetime regions are avoided in absorbers because this can create difficulty in collecting photo-generated carriers; here however, the low lifetime region is designed to prevent electrical crosstalk between neighboring pixel regions that can occur during simultaneous dual-band operation.

The details of one or more embodiments of the disclosure are set forth in the accompanying drawings and the description below. Other features, objects, and advantages of the disclosure will be apparent from the description and drawings, and from the claims.

### DESCRIPTION OF DRAWINGS

FIG. 1 is a diagrammatical cross sectional sketch of a dual band detector according to the PRIOR ART;

FIG. 2 is a diagrammatical cross sectional sketch of a dual band detector according to the PRIOR ART;

FIG. 3 is a cross sectional diagrammatical side view of a portion of a focal plane array according to the invention;

FIG. 4 is a diagrammatical cross sectional sketch of an exemplary one of the dual band detector used in the array of FIG. 3 according to the disclosure; and

FIG. 5 is a diagrammatical cross sectional sketch of a dual band detector used in the array of FIG. 3 according to another embodiment of the disclosure.

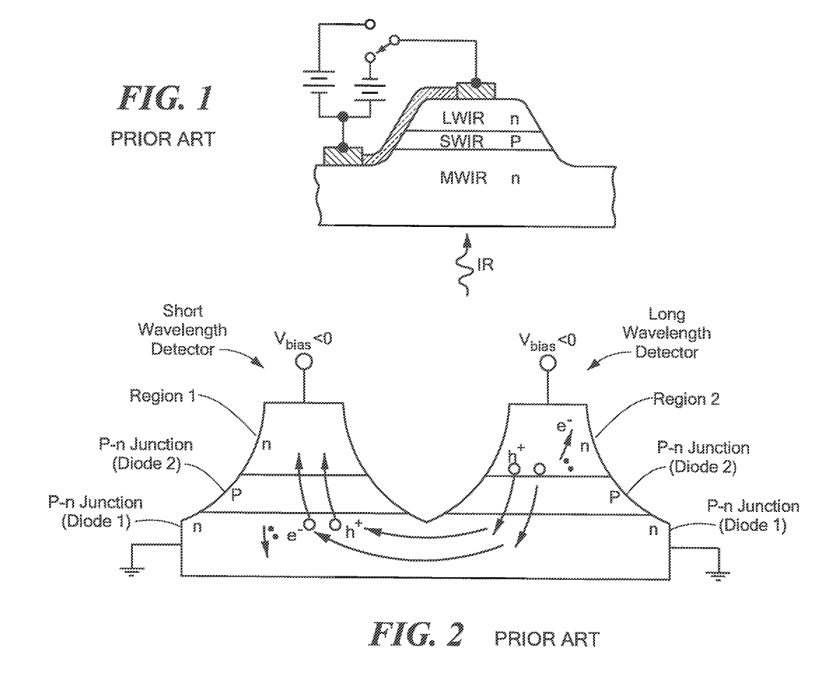

Like reference symbols in the various drawings indicate like elements.

### DETAILED DESCRIPTION

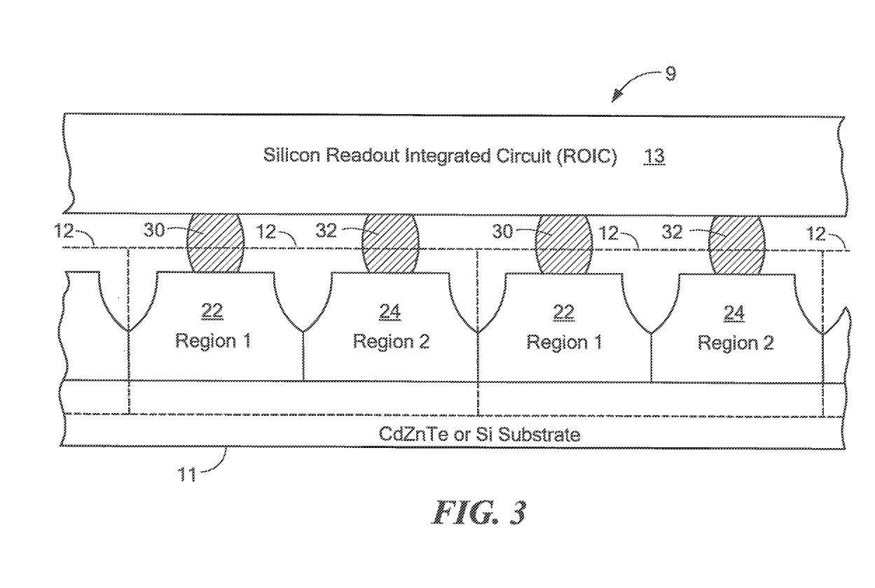

Referring now to FIG. 3, a focal plane array 9, here for example, a staring array, is shown having a detector array semiconductor Column II-VI chip 11 electrically connected to a first semiconductor (here for example, silicon) ROIC chip 13 through here for example with Indium electrical contacts or “bumps” 30, 32 in a stacked arrangement, as shown in FIG. 3, here using indium bump bonding technology.

More particularly, the chip 11 has an array of electromagnetic wave energy or radiation detectors 12, here for example, IR detectors, to generate an image of a target., is shown. Each detector 12 has two regions, REGION 1 and REGION 2, and provides a corresponding one of a plurality of pixels for the array 10. More particularly, each detector is a dual-band detector; REGION 1 detecting energy in one band or color and REGION 2 detecting energy in a different band of color. Thus, each individual detector 12 measures the intensity of electromagnetic wave energy or radiation, here, for example, infrared (IR) radiation incident upon the detector element in two bands and forms one pixel of the output image.

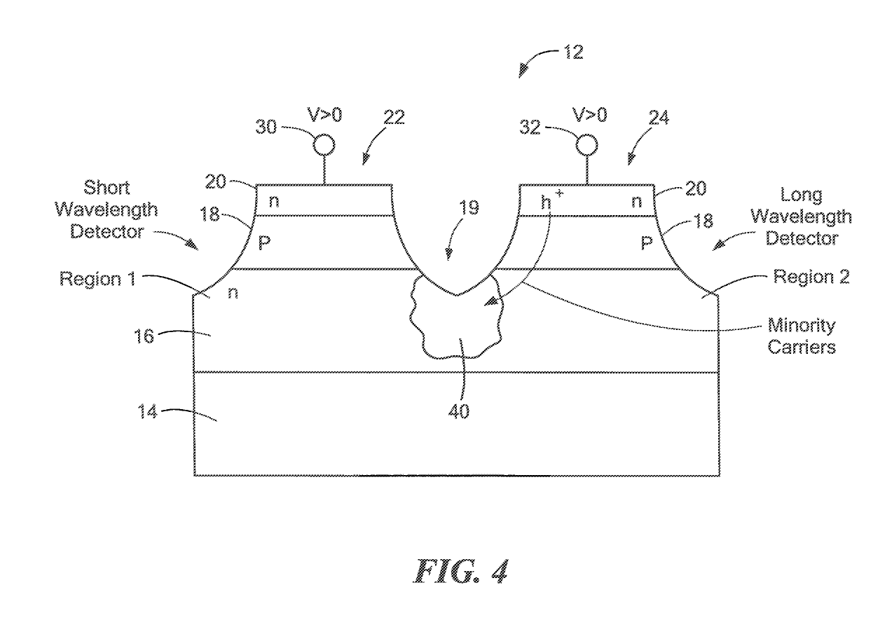

An exemplary one of the detectors 12 is shown in FIG. 4 to include a base, here, for example, a single crystal substrate 14, here CdZnTe or silicon. A layer 16 of single crystal n-type doped HgCdTe is epitaxially grown on the substrate 12. A p-type doped layer 18 of single crystal HgCdTe is epitaxially formed on the n-type doped layer 16. A second n-type doped layer 20 of single crystal HgCdTe is epitaxially formed on the p-type doped layer 18. The structure is processed using conventional photolithographic chemical etching techniques to form a trench 19 passing vertically through layers 20, 18 and into the upper portion of common layer 16, as shown, and thereby divide the detector 10 into two mesas 22, 24 having the n-type doped layer 16 as a common n-type doped layer; mesa 22 being response to IR energy having a wavelength in one band, here a low wavelength band of wavelengths, here for example, between 3 μm and 6 μm and mesa 24 being response to IR energy in a higher wavelength band, here for example, between 6 m and 10 m.

It should be understood that detectors 18 may be nBn detectors, or pBp detectors having a barrier layer B disposed between two same type conductivity semiconductor layers; in which case layer 18 would be a barrier layer to provide an nBn or pBp structure,

Here, the thickness of layer 16 is between 1 and 10 microns. The thickness of layer 18 is between 1 and 5 microns and the thickness of layer 20 is 1 to 10 microns. A first electrical contact 30 is an ohmic contact with the upper n-type layer 20 of mesa 22 and a second electrical contact 32 is in ohmic contact with the upper n-type layer 20 of mesa 24, as shown. The lower n-type layer 16 is grounded. The bandgap of the lower n-type layer 16 is greater than the bandgap of the upper n-type doped layer 20 and the bandgap of the p-type layer 18 is greater than both the bandgap of the upper 18 and lower n-type doped layers 16. More particularly, a layer 16 has an energy bandgap responsive to radiation in a first spectral region and layer 20 has an energy bandgap responsive to radiation in a second spectral region.

The contact 30 is connected to a negative voltage source forward biasing a p-n junction formed between layers 18 and 20 of mesa 22. The contact 32 is connected to a positive voltage source reverse biasing a p-n junction formed between layers 18 and 20 of mesa 24. Thus, the mesa 22 is biased with a negative voltage (forward biasing the junction between the upper n-type layer 20 and the p-type layer 18). The mesa 24 is biased with a positive voltage (reverse biasing the junction between the upper n-type layer 20 and the p-type layer 18).

More particularly, electromagnetic wave energy received having the longer wavelength, λ₂ generates electron and hole carriers in the upper n-type doped layer 20 and these carriers are separated, as indicated, into holes (h⁺) and electrons (e⁻) by the negative, i.e., reverse, bias across the long wavelength junction (i.e., the junction formed between the upper n-type layer 20 and the p-type layer 18) with the electrons e⁻ generating a majority carrier signal through the contact 32 to mesa 24. It is noted that the short wavelength junction (i.e., the junction formed between the lower n-type layer 16 and the p-type layer 18) is forward biased and therefore does not separate carriers generated in response to any received short wavelength, λ₁ electromagnetic wave energy. Electromagnetic wave energy received having the shorter wavelength, λ₁ generates electron and hole carriers in the lower n-type doped layer 16 and these carriers are separated, as indicated, into holes (h) and electrons (e) by the reverse bias across the short wavelength junction (i.e., the junction formed between the lower n-type layer 16 and the p-type layer 18) and a signal is generated in mesa 22. It is noted that the long wavelength junction (i.e., the junction formed between the upper n-type layer 20 and the p-type layer 28) is forward biased and therefore does not separate carriers generated in response to any received long wavelength, λ₂ electromagnetic wave energy.

The structure includes a barrier region 40 disposed in the common layer 16 between the pair of mesa 22, 24 to prevent unwanted carriers, here minority carriers (holes h) generated in mesa 24 from passing through the barrier region 40 between from mesa 24 to mesa 22. Here, for example, the barrier region 40 is a recombination region disposed in the common layer 16 between the pair of mesa 22, 24 to provide recombination to unwanted minority carriers passing through the region between the mesas 22, 24.

Here, for example the barrier region 40 has a high doping concentration of n-type dopant, (i.e., an n⁺ doped region) that is the higher doping concentration that the n-type doping concentration in layer 16 or and 18 thereby causing recombination of the minority carriers (holes h⁺) tending to diffuse from mesa 24 towards mesa 22 and concomitant cross talk between the two mesas. Alternative region 40 may be a region of damaged crystallographic structure or converted into a polycrystalline region. Thus, the barrier region 40 is a recombination region 40 and includes a low carrier lifetime layer to reduce the number of carrier passing between the adjacent mesas 22, 24 by increasing recombination of minority carriers and majority carriers.

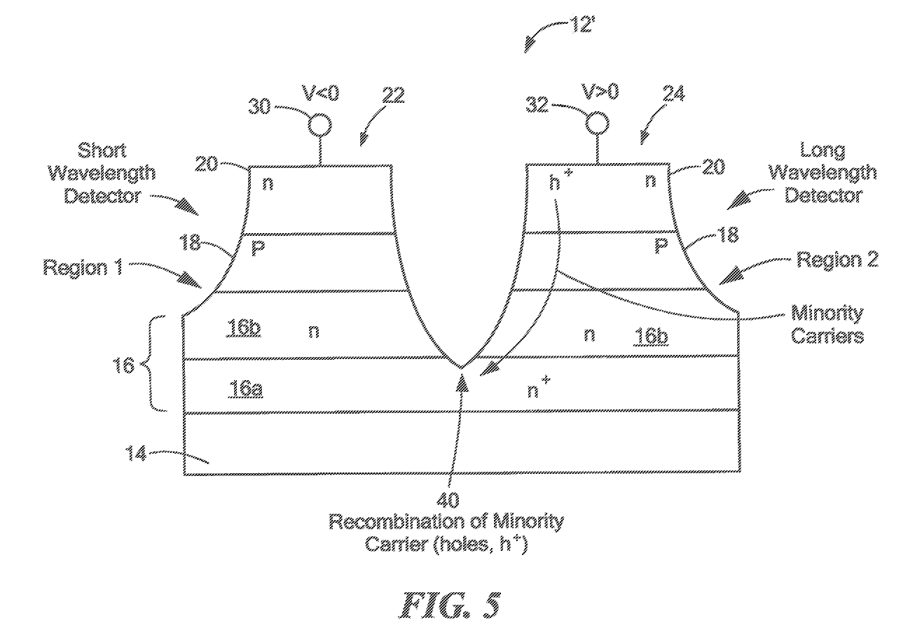

Referring now to FIG. 5, the detector 12′ has the lower layer 16 separated into two layer portions; a lower layer portion 16a and an upper layer portion 16b, is shown. The lower layer portion 16a of lower layer 16 is a common layer for the mesas 22, 24 and is here an n⁺ type layer (here the same, more heavily n-typed doping concentration used for region 40 in FIG. 3) while the upper layer portion 16b is divided between the two mesas 22, 24 with both having an n-type doping concentration, here for example, the same as the doping concentration of layer 16 in FIG. 4. Here, lower layer portion 16a, here for example, formed by molecular beam epitaxy (MBE) has a thickness of 1-5 microns while upper layer portion layer 16b also has a thickness of 1-5 microns so that the total thickness of layer 16, made up of lower layer portion 16a and upper layer portion 16b is the same as the thickness of layer 16 in FIG. 4. The bandgap of the n-type upper layer portion 16b is greater than the bandgap of the upper n-type doped layer 20 and the bandgap of the p-type layer 18 is greater than both the bandgap of the upper layer portion 16b and layer 18. Here, the structure is processed using conventional photolithographic chemical etching techniques to form a trench 19 passing vertically through layers 20, 18 and the upper portion 16b of layer 16 into the lower portion 16b of layer 16, as shown, and thereby divide the detector 10 into the two mesas 22, 24 having the n-type doped upper layer portion 16b. Again, mesa 22 is response to IR energy having a wavelength in one band, here a low wavelength band of wavelengths, here for example, between 3 μm and 6 μm and mesa 24 is response to IR energy in a higher wavelength band, here for example, between 61 μm and 10 μm.

Thus, the mesa 22 is biased with a negative voltage (forward biasing the junction between the upper n-type layer 20 and the p-type layer 18 while reverse biasing the junction between the p-type layer 20 and the upper layer portion 16b of n-type layer 16) to detect electromagnetic wave energy received having a shorter wavelength, Xk while the mesa 24 is biased with a positive (reverse biasing the junction between the upper n-type layer 20 and the p-type layer 18 to detect electromagnetic wave energy received having a longer wavelength, λ₂.

The lower layer portion 16a of layer 16 being a heavily doped n⁺ layer provides a barrier region 40 by causing a recombination of unwanted minority carriers passing through the region between the mesas 22, 24.

A number of embodiments of the disclosure have been described. Nevertheless, it will be understood that various modifications may be made without departing from the spirit and scope of the disclosure. For example, the wavelengths of interest may differ from those listed above. A dual-band long wave detector with response between 6 μm and 8 μm for band 1 and response between 8 μm and 10 μm for band 2 can be imagined. The thickness of the various layers can be adjusted to improve and optimize detector performance for a particular application. Alternative semiconductor, substrate materials, and detector designs can be used. For example, II-V type semiconductors on alternative substrates such as GaSb, Sapphire, or SiC. Accordingly, other embodiments are within the scope of the following claims.

What is claimed is:

1. A radiation detector, comprising:
a pair of adjacent mesas disposed on a common layer
wherein the common layer comprises:
a first semiconductor layer having a first conductivity type and an energy bandgap responsive to radiation in a first spectral region.
wherein each of the mesas comprises:
a second semiconductor layer disposed on the common layer having a conductivity type opposite the first conductivity type; and
a third semiconductor layer disposed on the second semiconductor layer having the first conductivity type and an energy bandgap responsive to radiation in a second spectral region;
wherein the third semiconductor layer of the second mesa produces minority carriers, in response to the radiation in the second spectral region, flowing as unwanted carriers into the common layer towards the first mesa; and
a barrier region disposed in the common layer to prevent the unwanted carriers from passing from the second mesa to the first mesa.

2. The radiation detector recited in claim 1 wherein the third semiconductor material has a predetermined doping concentration, and wherein the barrier region is a semiconductor region having the first electrical conductivity type and having as doping concentration greater than the predetermined doping concentration.

3. The radiation detector recited in claim 1 wherein the barrier region comprises a fourth semiconductor layer disposed on the first semiconductor layer, wherein the first semiconductor material has a predetermined doping concentration and wherein the fourth semiconductor layer has the first electrical conductivity type and has a doping concentration greater than the predetermined doping concentration.

4. The dual band detector structure recited in claim 3 wherein the barrier region provides recombination to minority carriers passing through the barrier region between the pair of mesa structures.

5. The dual band detector structure recited in claim 4 wherein the recombination region reduces the unwanted carriers passing between the mesa structures by recombining the unwanted minority carriers with majority carriers in the barrier region.

6. The dual band detector structure recited in claim 1 wherein the mesas are single crystalline and wherein the barrier region is polycrystalline.

7. The dual band detector structure recited in claim 1 wherein the barrier region is an implanted region.

8. A radiation detector comprising:
a pair of adjacent mesa structures disposed on a common layer, the common layer comprising:
a first semiconductor layer having a first type of electrical conductivity and an energy bandgap responsive to radiation in a first spectral region;
each one of the mesa structures, comprising:
a second semiconductor layer disposed on with the common layer, the second semiconductor layer having a second type of electrical conductivity opposite the first type of electrical conductivity;
a third semiconductor layer disposed on and in contact with the second semiconductor layer, the third semiconductor layer having the first type of electrical conductivity and an energy bandgap responsive to radiation in a second spectral region spectral region;
wherein a first one of the mesa structures is coupled to a voltage to forward bias a junction between the second semiconductor layer and the third semiconductor layer;
wherein a second one of the mesa structures is coupled to a voltage to reverse bias a junction between the second layer and the third semiconductor layer;
wherein the third semiconductor layer of the second one of the mesa structures produces minority carriers in response to the radiation in the second spectral region, a portion of such generate minority carriers flowing as unwanted carriers into the common layer towards the first one of the mesa structures; and
a barrier region disposed in the common layer between the pair of mesa structures to prevent the unwanted carriers from passing through the barrier region from the second one of the pair of mesa structures to the first one of the pair of mesa structures.

9. The radiation detector recited in claim 8 wherein the first semiconductor material has a predetermined doping concentration, and wherein the barrier region is a semiconductor region having the first electrical conductivity type and having a doping concentration greater than the predetermined doping concentration.

10. The radiation detector recited in claim 8 including the barrier region comprises a fourth semiconductor layer disposed on the first semiconductor layer, wherein the first semiconductor material has a predetermined doping concentration and wherein the fourth semiconductor layer has first electrical conductivity type and has a doping concentration greater than the predetermined doping concentration.

11. The dual band detector structure recited in claim 10 wherein barrier region provides recombination to minority carriers passing through the barrier region between the pair of mesa structures.

12. The dual band detector structure recited in claim 11 wherein the recombination region reduces the unwanted carrier passing between the adjacent mesa structures by recombining the unwanted minority carriers with majority carriers in the barrier region.

13. The dual band detector structure recited in claim 8 wherein the pair of mesa structures are single crystalline and wherein the barrier region is polycrystalline.

14. The dual band detector structure recited in claim 8 wherein the barrier region is an implanted region.

15. A dual-band detector structure, comprising:
a first semiconductor layer having a first type dopant and having an energy bandgap responsive to radiation in a first spectral region;
a second semiconductor layer having a second type dopant opposite to the first type dopant, the first semiconductor layer and the second semiconductor layer forming a first p-n junction;
a third semiconductor layer on the second semiconductor layer having the first type dopant and an energy bandgap responsive to radiation in a second spectral region spectral region, the second and third semiconductor layer forming a second p-n junction;
a trench passing vertically through the third semiconductor layer, through the second semiconductor layer and into an upper portion of the first semiconductor layer to separate the detector structure into a pair of detector regions;
a first electrical contact connected to the third semiconductor layer of a first one of the detector regions;
a second electrical contact connected to the third semiconductor layer of a second one of the pair of detector regions.
a first voltage connected to the first electric contact to reverse bias the second p-n junction of the first one of the pair of detector regions and forward bias the first p-n junction of the first one of the pair of detector regions;
a second voltage connected to the second electrical contact to forward bias the second p-n junction of the second one of the of detector regions and reverse bias the first p-n junction of the second one of the pair of detector regions;
wherein the third semiconductor layer of the first one of the detector regions produces minority carriers in response to the radiation in the second spectral region, a portion of such generate minority carriers flowing as unwanted carriers into towards the second one of the detector regions; and
a barrier region disposed between the pair of detector regions to prevent the unwanted carriers from passing through the barrier region from the first one of the detector regions to the second one of the detector regions.

16. The detector structure recited in claim 15 wherein the barrier region is a recombination region disposed in the first layer between the pair of detector regions to provide recombination to unwanted carriers passing through the barrier region between the pair of detector regions.

17. The dual band detector structure recited in claim 18 wherein the recombination region provides recombination to minority carriers passing through the barrier region between the pair of detector regions.

18. The dual band detector structure recited in claim 17 wherein the recombination region reduces the unwanted carrier passing between the adjacent mesa structures by recombining the unwanted minority carriers with majority carriers in the barrier region by increasing recombination of minority carriers and majority carriers.

19. The dual band detector structure recited in claim 17 wherein the recombination region has the same dopant type as the first doped layer with a doping concentration greater than the doping concentration of the first doped layer.

20. The dual band detector structure recited in claim 15 wherein the pair of detector regions are single crystalline and wherein the recombination region is polycrystalline.

21. The dual band detector structure recited in claim 1 wherein the pair of detector regions are single crystalline and wherein the barrier region is polycrystalline.

22. The dual band detector structure recited in claim 1 wherein the barrier region is an implanted region.

23. A radiation detector, comprising:
a pair of adjacent mesas disposed on a common layer
wherein the common layer comprises:
a first semiconductor layer having a first conductivity type and an energy bandgap responsive to radiation in a first spectral region.
wherein each of the mesas comprises:
a second semiconductor layer disposed on the common layer, and
a third semiconductor layer disposed on the second semiconductor layer having the first conductivity type and an energy bandgap responsive to radiation in a second spectral region;
wherein the second semiconductor layer inhibits a flow of majority carriers between the first semiconductor layer and the third semiconductor layer,
wherein the third semiconductor layer of the second mesa produces minority carriers, in response to the radiation in the second spectral region, flowing as unwanted carriers into the common layer towards the first mesa; and
a barrier region disposed in the common layer to prevent the unwanted carriers from passing from the second mesa to the first mesa.

24. A radiation detector, comprising:
a pair of adjacent mesas disposed on a common layer
wherein the common layer comprises:
a first semiconductor layer having a first conductivity type and an energy bandgap responsive to radiation in a first spectral region.
wherein each of the mesas comprises:
a second semiconductor layer disposed on the common layer; and
a third semiconductor layer disposed on the second semiconductor layer having the first conductivity type and an energy bandgap responsive to radiation in a second spectral region;
wherein the third semiconductor layer of the second mesa produces minority carriers, in response to the radiation in the second spectral region, flowing as unwanted carriers into the common layer towards the first mesa; and
a barrier region disposed in the common layer to prevent the unwanted carriers from passing from the second mesa to the first mesa.

25. The radiation detector recited in claim 24 wherein the second layer has a conductivity type opposite the conductivity type of the first layer.

26. The radiation detector recited in claim 24 wherein the second layer is a barrier layer.

27. The radiation detector recited in claim 24 wherein the first, second and third layers provide a nBn or pBp structure,
